(19) United States
(12) Patent Application Publication
(10) Pub. No.: US 2020/0105997 A1
(43) Pub. Date: Apr. 2, 2020

(54) MAGNETOSTRICTION ELEMENT AND METHOD OF MANUFACTURE OF MAGNETOSTRICTION ELEMENT

(71) Applicant: Panasonic Intellectual Property Management Co.,Ltd., Osaka (JP)

(72) Inventors: TAICHI NAKAMURA, Osaka (JP); KAZUKI SAKAI, Osaka (JP); MASAYA SHIROTANI, Osaka (JP); RYOU KUWABARA, Osaka (JP)

(21) Appl. No.: 16/460,223

(22) Filed: Jul. 2, 2019

(30) Foreign Application Priority Data
Sep. 27, 2018 (JP) 2018-182421

(51) Int. Cl. H01L 41/12; H01L 41/20; H01L 41/06

(52) U.S. Cl. CPC H01L 41/12; H01L 41/06; H01L 41/20

(57) ABSTRACT

Provided herein is an FeGa-base magnetostriction element that has specific characteristics with regards to magnetostriction along the longitudinal direction, and that shows a sufficiently high magnetostriction level along the longitudinal direction. The magnetostriction element is formed of a magnetostrictive material that is a monocrystalline alloy represented by Fe_{(100-α)}Ga_{α} (α represents the Ga content (at %), and satisfies 14≤α≤19) or Fe_{(100-α-β)}Ga_{α}X_{β} (α and β represent the Ga content (at %) and the X content (at %), respectively, X is at least one element selected from the group consisting of Sm, Eu, Gd, Tb, Dy, Cu, and C, and the formula satisfies 14≤α≤19, and 0.5≤β≤1). The magnetostriction element has a longitudinal direction with a first dimension, and a transverse direction with a second dimension smaller than the first dimension, the transverse direction being orthogonal to the longitudinal direction, and the longitudinal direction being parallel to the <100> crystal orientation of the monocrystalline alloy. The magnetostriction element, under a magnetic field applied parallel to an x-y plane of an x-axis representing the transverse direction and a y-axis representing the longitudinal direction and within an angle θ of 0°≤θ≤90° with respect to the x-axis, has an Lmax and an Lmin that satisfy 0≤Lmin≤Lmax/10, and 100 ppm≤Lmax≤1,000 ppm along the y-axis direction.

### TECHNICAL FIELD

The technical field relates to a magnetostriction element formed of an FeGa-base monocrystalline-alloy magnetostrictive material, and to a method of manufacture of the magnetostriction element.

### BACKGROUND

Recent years have seen the arrival of the Internet of things (IoT), a world where “things” equipped with autonomous communication functions automatically control one another by exchanging information. The spread of IoT means a society with increasing numbers of IoT devices featuring communication functions. IoT devices, such as sensors, require a power supply to operate. However, the needs for wirings and service time, and the cost make it difficult to provide power supplies for these proliferating numbers of devices. This has created a need for a power supply technology suited for IoT devices in the coming era of IoT. Against this background, an important consideration is a technology called “energy harvesting”, a process by which small amounts of energy from the everyday environment are converted into electrical power. Vibration is a form of energy source that is constantly produced by moving objects such as automobiles, trains, machinery, and humans in many places, and represents an energy source that is not influenced by weather or climate. It is therefore envisioned that a system that enables vibration-based power to be used as a power supply to applications coupled to movement of moving objects such as above can open the door to a more effective IoT.

Vibration-based power generation can be divided into four categories: magnetostrictive, piezoelectric, electrostatic induction, and electromagnetic induction. In magnetostrictive power generation, a leakage magnetic flux due to a change in magnetic field inside a magnetostrictive material in response to applied stress is converted into electrical energy through a coil wrapped around the magnetostrictive material. The magnetostrictive power generation involves a smaller internal resistance, and generates more power than the other types of vibration-based power generation. Another characteristic of the magnetostrictive power generation is the desirable durability due to the metal alloy used as magnetostrictive material. This makes the magnetostrictive power generation a desirable mode of power generation that could overcome an issue associated with magnetostriction-type vibration powered generators or elements, namely, the durability of magnetostriction-type vibration powered generators or elements.

As an example, a magnetostriction element is available that is formed by cutting an FeGa monocrystalline alloy by discharge machining in a direction that aligns with the <100> orientation of the monocrystal. To produce such a magnetostriction element, a molten FeGa alloy is lifted out of a tubular furnace at a certain rate using a lifter to allow the molten metal to unidirectionally solidify from bottom to top. By solidifying in this fashion, the crystals can grow along the <100> orientation. The solidified steel ingot is then separated into monocrystals, and cut by discharge machining in a direction that aligns with the <100> orientation of the monocrystal to obtain individual magnetostriction elements (see WO2016/121132).

When such a magnetostriction element is to be used in actual applications such as in a magnetostriction-type vibration-powered generator, an important consideration in terms of improving power output and device quality is how to bring about sufficient magnetostriction along the longitudinal direction of the magnetostriction element, and how to reduce the variation that occurs in the magnetostriction characteristics of the magnetostriction elements used in these applications. Magnetostriction elements produced by a traditional method such as above have variation in magnetostriction characteristics (or magnetic anisotropy). Specifically, the method described in the foregoing related art does not necessarily always produce a magnetostriction element that has its magnetostriction maximized along the longitudinal direction, although the magnetostriction element is obtained by cutting a solidified steel ingot in a direction that aligns with the <100> orientation of the monocrystal. For example, the magnetostriction elements produced by the related art may include a magnetostriction element that has its magnetostriction maximized along the transverse direction. Even if the method successfully produced magnetostriction elements of characteristics with the magnetostriction maximized along the longitudinal direction, variation may occur in the specific magnetostriction characteristics. To describe more specifically, because of small errors occurring in the growth time of crystals and the proportions of components such as Ga concentration (at %), the magnetostriction elements produced by the method of the foregoing related art do not have similar characteristics with regard to magnetostriction along the longitudinal direction, and do not necessarily show sufficiently high magnetostriction levels (ppm) along the longitudinal direction.

The traditional method of manufacturing magnetostriction elements thus requires evaluating the magnetostriction characteristics of each element, and screening for magnetostriction elements of the desired magnetostriction characteristics. Specifically, the method requires screening for only magnetostriction elements having similar specific characteristics with regards to magnetostriction and showing sufficiently high magnetostriction levels along the longitudinal direction. Such screening procedures can lead to poor yield.

### SUMMARY

It is accordingly an object of the present disclosure to provide an FeGa-base magnetostriction element that has specific characteristics with regards to magnetostriction along the longitudinal direction, and that shows a sufficiently high magnetostriction level along the longitudinal direction. The present disclosure is also intended to provide a method of manufacture of such a magnetostriction element, whereby the FeGa-base magnetostriction elements it produces have small variation in magnetostriction characteristics, and can be manufactured with improved yield.

According to a first gist of the present disclosure, there is provided a magnetostriction element comprised of a magnetostrictive material that is a monocrystalline alloy represented by the following formula (1) or (2),

Fe_{(100-α)}Ga_{α} (1)

wherein α represents the Ga content (at %), and satisfies 14≤α≤19,

Fe_{(100-α-β)}Ga_{α}X_{β} (2)

wherein α and β represent the Ga content (at %) and the X content (at %), respectively, X is at least one element selected from the group consisting of Sm, Eu, Gd, Tb, Dy, Cu, and C, and the formula satisfies 14≤α≤19, and 0.5≤β≤1,

the magnetostriction element having a longitudinal direction with a first dimension, and a transverse direction with a second dimension smaller than the first dimension, the transverse direction being orthogonal to the longitudinal direction, and the longitudinal direction being parallel to the <100> crystal orientation of the monocrystalline alloy,

the magnetostriction element under a magnetic field applied parallel to an x-y plane formed by an x-axis representing the transverse direction and a y-axis representing the longitudinal direction and within an angle θ of 0°≤θ≤90° from an origin of the x-y plane with respect to the x-axis having an Lmax with the angle θ of applied magnetic field satisfying 80°≤θ≤90°, and an Lmin with the angle θ of applied magnetic field satisfying 0°≤θ≤10°, wherein Lmax is a maximum value of magnetostriction level L measured along the y-axis direction, and Lmin is a minimum value of magnetostriction level L measured along the y-axis direction, and

the Lmax and the Lmin satisfying 0≤Lmin≤Lmax/10, and 100 ppm≤Lmax≤1,000 ppm.

In an aspect of the first gist of the present disclosure, the magnetostriction element may have a form of a plate with two opposing principal surfaces, and the two opposing principal surfaces may be parallel to the x-y plane.

According to a second gist of the present disclosure, there is provided a method for manufacturing a magnetostriction element,

the method comprising:

producing a monocrystalline alloy represented by the following formula (1) or (2),

Fe_{(100-α)}Ga_{α} (1)

wherein α represents the Ga content (at %), and satisfies 14≤α≤19,

Fe_{(100-β-β)}Ga_{α}X_{β} (2)

wherein α and β represent the Ga content (at %) and the X content (at %), respectively, X is at least one element selected from the group consisting of Sm, Eu, Gd, Tb, Dy, Cu, and C, and the formula satisfies 14≤α≤19, and 0.5≤β≤1;

cutting the monocrystalline alloy into a shape having a longitudinal direction with a first dimension, and a transverse direction with a second dimension smaller than the first dimension, the transverse direction being orthogonal to the longitudinal direction, and the longitudinal direction being parallel to the <100> crystal orientation of the monocrystalline alloy; and

subjecting the cut monocrystalline alloy to a heat treatment at 400° C. or more to 700° C. or less,

the monocrystalline alloy being cut before or after the heat treatment.

In an aspect of the second gist of the present disclosure, the monocrystalline alloy after being cut may have a form of a plate with two opposing principal surfaces.

In an aspect of the second gist of the present disclosure, the heat treatment may be performed in an inert gas atmosphere.

The present disclosure has provided an FeGa-base magnetostriction element that has specific characteristics with regards to magnetostriction along the longitudinal direction, and that shows a sufficiently high magnetostriction level along the longitudinal direction. The present disclosure has also provided a method of manufacture of such a magnetostriction element, whereby the FeGa-base magnetostriction elements it produces have small variation in magnetostriction characteristics, and can be manufactured with improved yield.

### BRIEF DESCRIPTION OF THE DRAWINGS

FIG. 1 is a perspective view schematically illustrating a magnetostriction element of an embodiment of the present disclosure.

FIG. 2 is a flowchart representing a method for manufacturing the magnetostriction element of the embodiment of the present disclosure.

FIG. 3 is a schematic view describing a characteristic of the magnetostriction element of the embodiment of the present disclosure.

### DESCRIPTION OF EMBODIMENTS

The following describes a magnetostriction element, and a method of manufacture thereof according to an embodiment of the present disclosure. It is to be noted that the present disclosure is not limited to the embodiments below.

A magnetostriction element of an embodiment of the present disclosure is formed of a magnetostrictive material that is a monocrystalline alloy represented by the following formula (1) or (2) (hereinafter, also referred to as “monocrystalline alloy of formula (1) or (2)”),

Fe_{(100-α)}Ga_{α}X_{β} (1)

wherein α represents the Ga content (at %), and satisfies 14≤α≤19,

Fe_{(100-α-β)}Ga_{α}X_{β} (2)

wherein α and β represent the Ga content (at %) and the X content (at %), respectively, X is at least one element selected from the group consisting of Sm, Eu, Gd, Tb, Dy, Cu, and C, and the formula satisfies 14≤α≤19, and 0.5≤β≤1.

The monocrystalline alloy of formula (1) shows desirable magnetostriction characteristics with Ga dissolving in Fe in the form of a solid solution. The monocrystalline alloy of formula (2) shows more desirable magnetostriction characteristics when Ga is replaced in part with a third element (at least one element selected from the group consisting of Sm, Eu, Gd, Tb, Dy, Cu, and C, particularly, one element selected from this group). However, the elements other than Fe are contained to such an extent that the amount of solid solution relative to Fe does not alter the crystal structure. Specifically, the amount is 20 at % or less, a value sufficiently smaller than the probable solid solubility limit of 30 at % against Fe. Preferably, X, which is a third element in formula (2), may be at least one element selected from the group consisting of Sm, Cu, and C.

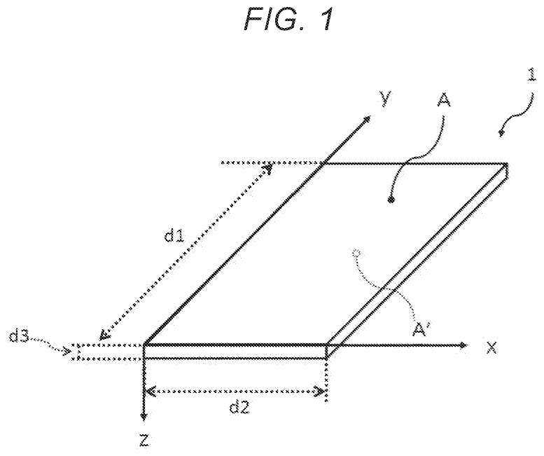

FIG. 1 is a perspective view schematically representing a magnetostriction element 1 of the embodiment of the present disclosure. As illustrated in FIG. 1, the magnetostriction element 1 has an x axis, a y axis, and a z axis representing a transverse, a longitudinal, and a thickness direction, respectively. These axes are orthogonal to one another with an origin (x=y=z=0) at the bottom left corner on the top surface of the magnetostriction element 1. The magnetostriction element 1 has a first dimension d1 along the y axis representing a longitudinal direction, a second dimension d2 along the x axis representing a transverse direction, and a third dimension d3 along the z axis representing a thickness direction. The second dimension d2 is smaller than the first dimension d1. The magnetostriction element 1 is plate-like in shape with two opposing principal surfaces A and A′ (the principal surface A′ is on the back opposite the principal surface A in the perspective view of the magnetostriction element 1 shown in FIG. 1) parallel to a plane formed by x and y axes (hereinafter, also referred to as “x-y plane”). The longitudinal direction of the magnetostriction element 1 is parallel to the <100> crystal orientation of the monocrystalline alloy of formula (1) or (2).

For convenience of explanation, the magnetostriction element 1 shown in FIG. 1 has a form of a plate with the x, y, and z axes set along the transverse, longitudinal, and thickness direction. These axes are orthogonal to one another with an origin at the bottom left corner of the principal surface A of the magnetostriction element 1, and the opposing principal surfaces A and A′ are parallel to the x-y plane. However, the shape of the magnetostriction element 1 is not limited to this. Specifically, the magnetostriction element 1 may have any shape as may be suited for the use of the magnetostriction element 1 such as in a magnetostriction-type device, provided that the magnetostriction element 1 has a first dimension d1 along the longitudinal direction, and a second dimension d2 smaller than the first dimension d1 and extending along the transverse direction orthogonal to the longitudinal direction, and that the longitudinal direction is parallel to the <100> crystal orientation of the monocrystalline alloy of formula (1) or (2). For example, the magnetostriction element 1 may have a rectangular shape, a polygonal columnar shape, a columnar shape with a semicircular cross section, or some other solid shape.

In the case of a plate shape such as that shown in FIG. 1, for example, the first dimension d1 is 8 mm to 15 mm, preferably 9 mm to 12 mm, more preferably about 10 mm, the second dimension d2 is 2 mm to 7.5 mm, preferably 3 mm to 6.0 mm, more preferably about 5 mm, and the third dimension d3 is 0.5 mm to 3 mm, preferably 0.5 mm to 2 mm, more preferably about 1 mm. With a plate shape of these dimensions, the magnetostriction element 1 can be suitably applied to, for example, a small magnetostriction-type vibration-powered generator.

In the present disclosure, the content (or concentration) of each element in the monocrystalline alloy of formula (1) or (2) is the number fraction of atoms of each element with respect to the total number of atoms in the monocrystalline alloy, and is represented by at % (atomic percent). Specifically, the content of each element is a measured value from an analysis of the monocrystalline alloy with an electron probe microanalyzer (EPMA). More specifically, the content is a measured EPMA value by a spot analysis at different points of the magnetostriction element 1, or by a surface analysis of the magnetostriction element 1. To describe more specifically, the content is a mean value (at %) from an EPMA analysis of the magnetostriction element 1 at five arbitrarily chosen points on x-y plane. The monocrystalline alloy as the constituent magnetostrictive material of the magnetostriction element 1 of the present embodiment may contain trace amounts of unavoidable elements (for example, less than 0.005 at % of oxygen), provided that the monocrystalline alloy is configured essentially from the elements specified above.

The following describes other characteristics of the magnetostriction element 1, along with a method of manufacture of the magnetostriction element 1 of the embodiment of the present disclosure.

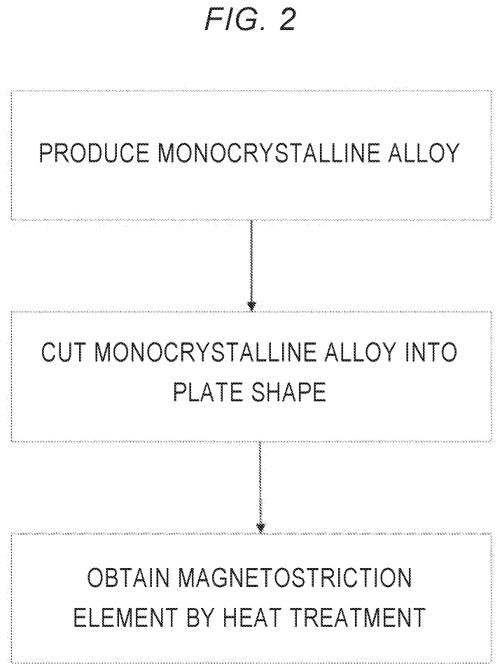

FIG. 2 is a flowchart representing a method for manufacturing the magnetostriction element 1 of the embodiment of the present disclosure. First, the monocrystalline alloy of formula (1) or (2) is produced, as shown in FIG. 2.

The monocrystalline alloy of formula (1) or (2) may be produced using an appropriately selected method of growing an alloy, and the method is not particularly limited. Examples of such methods include the Czochralski technique (CZ technique), the Bridgeman technique, and a rapid solidification method. With the CZ technique, large crystals can be produced with accurate chemical compositions and crystal orientations. Specifically, for example, a cylindrical monocrystalline alloy is produced using the CZ technique.

For example, in the production of a cylindrical monocrystalline alloy of formula (1) or (2) using the CZ technique, the concentration of the elements other than Fe, for example, the Ga concentration (at %) can increase (for example, monotonous increase) from an early growing portion (the portion that comes out of the crucible first) corresponding to the upper part of the cylindrical monocrystalline alloy to a late growing portion (the portion that comes out of the crucible late) corresponding to the lower portion of the cylindrical monocrystalline alloy. This is because of the width in the liquidus and the solidus line in the composition of the FeGa-base alloy. Even when the monocrystalline alloy produced by using the CZ technique shows, for example, such monotonous increase of Ga concentration, the content of each element in the monocrystalline alloy can be satisfied as in formula (1) or (2) by appropriately making adjustments in the EPMA analysis conducted in the manner described above.

Thereafter, as shown in FIG. 2, the monocrystalline alloy of formula (1) or (2) produced is cut into a plate form.

The shape is not limited to a plate form with two opposing principal surfaces A and A′, as mentioned above in conjunction with the shape of the magnetostriction element 1. Specifically, the monocrystalline alloy is cut into such a shape that the magnetostriction element 1 produced has the first dimension d1 along the longitudinal direction, and the second dimension d2 smaller than the first dimension D1 and extending in the transverse direction (orthogonal to the longitudinal direction), and the longitudinal direction is parallel to the <100> crystal orientation of the monocrystalline alloy of formula (1) or (2), as described above.

More specifically, the transverse direction (x-axis direction) or thickness direction (z-axis direction), or both of these axes are not necessarily required to be parallel to the <100> crystal orientation of the monocrystalline alloy, provided that at least the longitudinal direction (y-axis direction) is parallel to the <100> crystal orientation of the monocrystalline alloy of formula (1) or (2). That is, for example, it is not required for both of the transverse direction (x-axis direction) and the longitudinal direction (y-axis direction), or the x-y plane parallel to the transverse direction (x-axis direction) and the longitudinal direction (y-axis direction), to be parallel to the <100> crystal orientation of the monocrystalline alloy. As another example, it is not required for all of the transverse direction (x-axis direction), the longitudinal direction (y-axis direction), and the thickness direction (z-axis direction), or all of the x, y, and z axes of the cut shape, to be parallel to the <100> crystal orientation of the monocrystalline alloy. The magnetostriction element 1 can be obtained after a heat treatment of the cut monocrystalline alloy of formula (1) or (2), as described below. The magnetostriction element 1 can have a characteristic that shows a sufficiently high magnetostriction level along the longitudinal direction (y-axis direction) when placed under a magnetic field applied parallel to the x-y plane.

In the present disclose, the <100> crystal orientation of the monocrystalline alloy of formula (1) or (2) is determined by EBSD (Electron Backscatter Diffraction), though other known methods also may be used. The <100> orientation of the FeGa-base alloy is easily magnetizable. The magnetostriction element 1 of the present embodiment can therefore show a sufficiently high magnetostriction level along the longitudinal direction (y-axis direction) when the longitudinal direction (y-axis direction) is parallel to the <100> crystal orientation of the monocrystalline alloy. The magnetostriction element 1 can have a characteristic that shows a sufficiently high magnetostriction level along the longitudinal direction (y-axis direction) even when the longitudinal direction (y-axis direction) of the magnetostriction element 1 has an angle difference of 10° or less from the <100> crystal orientation of the monocrystalline alloy of formula (1) or (2), preferably as small as 80 or less, more preferably 60 or less, further preferably 40 or less, even more preferably 20 or less.

The monocrystalline alloy of formula (1) or (2) may be cut using a known technique, for example, such as wire discharge machining.

Thereafter, as shown in FIG. 2, the plate-shaped monocrystalline alloy is subjected to a heat treatment to obtain the magnetostriction element 1 of the present embodiment.

Specifically, the heat treatment is performed in an inert gas atmosphere. As used herein, “inert gas” means a noble gas such as argon or helium, or a low-reactive gas that does not easily undergo chemical reaction, for example, such as nitrogen. Preferred is argon.

The heat treatment method is not limited to a specific method, and may be, for example, a method using a known device (for example, an electrical resistance furnace).

The heat treatment temperature is not particularly limited, as long as it is no higher than the Curie temperature and above a temperature at which the monocrystalline alloy of formula (1) or (2) starts to undergo transformation. The heat treatment temperature does not greatly differ for the binary monocrystalline alloy of Fe_{(100-α)}Ga_{α} represented by formula (1), and for the ternary monocrystalline alloy of Fe_{(100-α-β)}Ga_{α}X_{β} represented by formula (2) because the amount of elements other than Fe is 20 at % or less in terms of a solid solution against Fe. Specifically, the heat treatment temperature is 400° C. to 700° C., preferably 500° C. to 650° C., more preferably 500° C. to 600° C., further preferably 550° C. to 600° C. The heating time at the heat treatment temperature may be, for example, preferably 3 to 7 hours, more preferably 4 to 6 hours, further preferably 4.5 to 5 hours, even more preferably 5 hours from the temperature reaching the upper limit of its range.

By the heat treatment of the cut monocrystalline alloy, the magnetic domains in the monocrystal can be made wider, and the magnetic energy can be stably reduced. This encourages the cut monocrystalline alloy to magnetize in its easily magnetizable direction. Particularly, stress due to the formation of an oxide film can be reduced when the heat treatment is performed in an inert gas (for example, argon) atmosphere.

In another embodiment, cutting of the monocrystalline alloy of formula (1) or (2), and the heat treatment of the monocrystalline alloy may be performed in reversed order in the method of manufacture of the magnetostriction element 1 described above. That is, the magnetostriction element 1 may be produced by cutting the monocrystalline alloy into the desired shape after the monocrystalline alloy of formula (1) or (2) is subjected to a heat treatment at the foregoing temperatures. The magnetostriction element 1 produced in this fashion should also have wide magnetic domains in the monocrystal before cutting as a result of the heat treatment, and the magnetic energy should be stably reduced as above. The magnetostriction element 1, upon being cut, should therefore have a characteristic that shows a sufficiently high magnetostriction level in the longitudinal direction (y-axis direction).

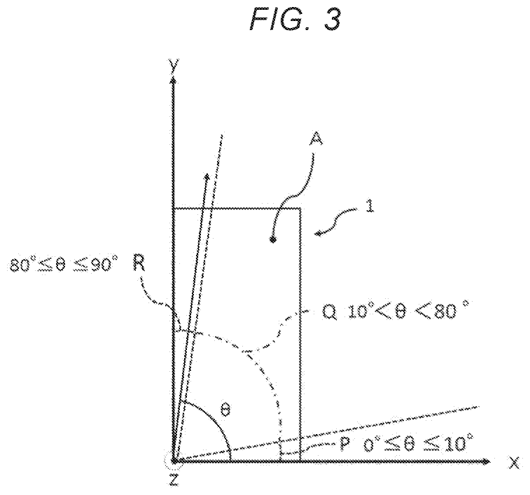

Another characteristic of the magnetostriction element 1 produced by using the foregoing method is described below, with reference to FIGS. 1 and 3. FIG. 3 is a schematic view describing a characteristic of the magnetostriction element 1 of the embodiment of the present disclosure.

The following describes the magnetostriction element 1 of FIGS. 1 and 3 of when a magnetic field parallel to the x-y plane formed by x and y axes is applied at an angle θ of 0°≤θ≤90° from the origin (x=y=0) of the x-y plane with respect to the x axis. For example, FIG. 3 shows an example of the angle θ of applied magnetic field, as indicated by arrow. Here, the magnetostriction element 1 satisfies 0≤Lmin≤Lmax/10, and 100 ppm≤Lmax≤1,000 ppm, where Lmax and Lmin represent the maximum and minimum values, respectively, of the magnetostriction level measured along the longitudinal direction (y-axis direction). Preferably, the magnetostriction element 1 satisfies 205 ppm≤Lmax≤1,000 ppm, more preferably 210 ppm≤Lmax≤1,000 ppm, further preferably 250 ppm≤Lmax≤1,000 ppm. That is, the magnetostriction element 1 satisfies specific ranges of numerical values with regard to the maximum and minimum values of the magnetostriction level measured along the longitudinal direction (y-axis direction), and shows a sufficiently high magnetostriction level along the longitudinal direction (y-axis direction).

Here, Lmax occurs when the angle θ of applied magnetic field satisfies 80°≤θ≤90°, and Lmin occurs when the angle θ of applied magnetic field satisfies 0°≤θ≤10°. To describe more specifically, as depicted in FIG. 3, because the magnetostriction element 1 shows a higher magnetostriction level along the longitudinal direction (y-axis direction), Lmax occurs with the angle θ falling in a range of 80°≤θ≤90°, or region R, and Lmin occurs with the angle θ falling in a range of 0°≤θ≤10°, or region P, when the angle θ of applied magnetic field is divided into a region P of 0°≤θ≤10°, a region Q of 10°<θ<80°, and a region R of 80°≤θ≤90° in the 0°≤θ≤90° range.

As used herein, “magnetostriction level (ppm)” refers to a percentage of dimensional change due to the magnetostriction effect of the magnetostrictive material. In the present disclosure, magnetostriction level is measured in a room-temperature environment (25° C.) using a common strain gauge method. Specifically, in the present disclosure, the magnetostriction level (ppm) of the magnetostriction element 1 is a measured value at saturated magnetization under an applied magnetic field parallel to the x-y plane of the magnetostriction element 1, as measured by a strain gauge installed in such an orientation that the gauge axis is parallel to the longitudinal direction (i.e., y-axis direction; parallel to the <100> crystal orientation of the monocrystalline alloy) of the x-y plane of the magnetostriction element 1. The measurement is made with a vibrating sample magnetometer (VSM) used as a magnetic field generator at a magnetic field intensity of 5,000 Oe.

Considering this definition of magnetostriction level (ppm), the magnetostriction level shows a large positive value when magnetostriction is large along the longitudinal direction (y-axis direction), whereas the magnetostriction level shows a large negative value when magnetostriction is large along the transverse direction (x-axis direction). Accordingly, the condition 0≤Lmin≤Lmax/10 means satisfying the specific range of magnetostriction characteristic where Lmin does not take negative values while being greatly different from Lmax (i.e., no magnetostriction level along the transverse direction (x-axis direction)). The condition 100 ppm≤Lmax≤1,000 ppm means that the magnetostriction level is sufficiently high along the longitudinal direction (y-axis direction).

In the method of manufacture of the magnetostriction element 1 described above, the monocrystalline alloy of formula (1) or (2) is subjected to a heat treatment after being cut into a plate form, and the magnetostriction elements 1 produced can have equally desirable magnetostriction characteristics. That is, the method encourages the monocrystalline alloy to magnetize in its easily magnetizable direction. That is, the magnetostriction elements 1 can have smaller variation in the magnetostriction characteristics along the longitudinal direction, and show a sufficiently high magnetostriction level in the longitudinal direction owing to the magnetostriction characteristics that are similarly desirable across the magnetostriction elements 1. This eliminates the need for screening or other such procedures in the production of magnetostriction element 1, and the yield can improve.

### EXAMPLES

The present disclosure is described below in greater detail by way of Examples and Comparative Examples. The present disclosure, however, is not limited by the following descriptions.

In Examples, plate-shaped magnetostriction elements, similar to that depicted in FIGS. 1 and 3, were made from an Fe_{(100-α)}Ga_{α} monocrystalline alloy, and the magnetostriction level at saturated magnetization was measured under applied magnetic field to each magnetostriction element to evaluate the effect of the presence or absence of a heat treatment in manufacture of the magnetostriction element.

### Production of Magnetostriction Element

Plate-shaped magnetostriction elements of Examples 1 to 6 and Comparative Examples 1 and 2 were made from an Fe_{(100-α)}Ga_{α} monocrystalline alloy.

First, Fe (purity 99.999%) and Ga (purity 99.999%) were weighed in appropriately adjusted amounts using an electronic balance.

Monocrystalline alloy specimens were grown using a high-frequency dielectric heating CZ furnace. A dense alumina crucible measuring 45 mm in outer diameter (ϕ) was disposed inside a graphite crucible having an inner diameter ϕ of 50 mm, and weighed 400 g of Fe and Ga was supplied as raw materials of each alloy specimen. The crucibles charged with the raw materials were placed in a growth furnace, and an argon gas was introduced after creating a vacuum inside the furnace. Heat was applied as soon as the pressure inside the furnace became atmospheric pressure, and the alloy was heated for 12 hours, until a melt was obtained. An FeGa monocrystal was cut to produce a seed crystal of <100> orientation, and the seed crystal was lowered down to the vicinity of the melt. While being rotated at 5 ppm, the seed crystal was gradually lowered toward the melt until the tip of the seed crystal contacted the melt. The crystal was grown by gradually decreasing temperature, before lifting the seed crystal at a rate of 1.0 mm/hr. This produced a monocrystalline alloy measuring 10 mm in diameter and 80 mm in length along the length of its body.

The monocrystalline alloy after wire discharge machining was cut into a 1 mm-thick plate shape having principal surfaces measuring 10 mm in length along the longitudinal direction, and 5 mm in width along the transverse direction. Here, the monocrystalline alloy was cut in such a manner that the growth direction of the monocrystalline alloy directed the same way as the longitudinal direction of the plate. Specifically, the plate had its longitudinal direction parallel to the <100> crystal orientation of the monocrystalline alloy after being cut. In Examples 1 to 3 and Comparative Example 1, the monocrystalline alloy was cut into a plate shape at a portion that had grown before other portions (the portion that comes out of the crucible first), that is, a portion closer to the top of the 80 mm-long alloy. On the other hand, in Examples 4 to 6 and Comparative Example 2, the monocrystalline alloy was cut into a plate shape at a portion that had grown after other portions (the portion that comes out of the crucible last), that is, a portion closer to the bottom of the 80 mm-long alloy.

In Examples 1 and 4 and Comparative Examples 1 and 2, the monocrystalline alloy was cut with no angle difference from the <100> crystal orientation of the x-y plane, as shown in the Table 1 below. Specifically, the monocrystalline alloy was cut parallel to the <100> crystal orientation not only along the longitudinal direction (y-axis direction) but along the transverse direction (x-axis direction). In Examples 2, 3, 5, and 6, the monocrystalline alloy was cut with an angle difference from the <100> crystal orientation, specifically, angle differences of 22.50, 450, 22.50, and 450 for the transverse direction (x-axis direction). The angle difference is a measured value of the difference from the <100> crystal orientation in the x-y plane as measured by EBSD.

In Examples 1 to 6, the plate-shaped monocrystalline alloy was subjected to a heat treatment in an argon atmosphere, using an electrical resistance furnace. In the heat treatment, heat was applied until the temperature reached the upper limit temperature of 600° C., and the monocrystalline alloy was further heated for 5 hours after the temperature reached this upper limit temperature. This produced magnetostriction elements similar to that schematically illustrated in FIGS. 1 and 3.

In Comparative Examples 1 and 2, the monocrystalline alloys were produced in the same manner as in Examples, except that the cutting procedure was not followed by the heat treatment.

### Evaluation of Magnetostriction Level of Magnetostriction Element

The magnetostriction level of each magnetostriction element was evaluated to see if there was variation in the magnetostriction characteristics of the magnetostriction elements produced.

The same coordinate axes schematically depicted in FIG. 3 were set on the principal surface of the plate observed, with the x axis representing the transverse direction, and the y axis representing the longitudinal direction. The thickness direction, which corresponds to z axis, is irrelevant in the evaluation of this Example. A magnetic field was applied to each magnetostriction element using a vibrating sample magnetometer (VSM). Here, the magnetic field was applied at an intensity of 5,000 Oe in a direction parallel to the x-y plane and at an angle θ of 0°≤θ≤90° from the origin (x=y=0) of the x-y plane with respect to the x axis. At saturation of magnetization, the magnetostriction element under the applied magnetic field in the 0°≤θ≤90° range was measured for maximum magnetostriction level (Lmax; ppm) and minimum magnetostriction level (Lmin; ppm) along the longitudinal direction (y-axis direction), and angles 9 with which Lmax and Lmin occurred. As described with reference to FIG. 3, the angle θ of applied magnetic field was divided into a region P of 0°≤θ≤10°, a region Q of 10°<θ<80°, and a region R of 80°≤θ≤90°. The magnetostriction level was measured in a room-temperature environment (25° C.) using a common strain gauge method. Specifically, the strain gauge was installed in such an orientation that the gauge axis was parallel to the longitudinal direction (y-axis direction) on the x-y plane of the plate-shaped magnetostriction element.

Table 1 shows the cut site, the Ga concentration (at %), and the angle difference from the <100> crystal orientation in the x-y plane of the Fe_{(100-α)}Ga_{α} monocrystalline alloy magnetostriction elements of Examples 1 to 6 and Comparative Examples 1 and 2. The table also shows the results of magnetostriction level evaluation, specifically, Lmax (ppm) and Lmin (ppm), and the angles θ with which Lmax and Lmin occurred.

TABLE 1

| | | Ga | | Lmax | | Lmin | |
|---|---|---|---|---|---|---|---|
| | Cut | concentration | Angle difference from <100> | | Angle θ | | Angle θ |
| | site | (at %) | crystal orientation in x-y plane | ppm | region | ppm | region |
| Ex. 1 | H | 15.1 | 0° | 315 | R | 10 | P |
| Ex. 2 | H | 15.2 | 22.5° | 320 | R | 10 | P |
| Ex. 3 | H | 15.0 | 45° | 310 | R | 10 | P |
| Ex. 4 | L | 18.1 | 0° | 320 | R | 10 | P |
| Ex. 5 | L | 18.3 | 22.5° | 325 | R | 10 | P |
| Ex. 6 | L | 18.2 | 45° | 315 | R | 10 | P |
| Com. Ex. 1 | H | 15.2 | 0° | 205 | R | −85 | P |
| Com. Ex. 2 | L | 18.2 | 0° | 30 | R | −300 | P |

In Table 1, cut site H means that the alloy was cut in a portion closer to the top of the alloy where growth takes place before other portions, and cut site L means that the alloy was cut in a portion closer to the bottom of the alloy where growth takes place after other portions. As mentioned above, the FeGa-base alloy composition has a width in the liquidus and the solidus line, and the Ga concentration increases with a gradient from early to late stages of crystalline growth. In this Example, the influence of the composition was examined by using the magnetostriction elements obtained by cutting the monocrystalline alloy at different cut sites where the growth time is different.

The Ga concentration (at %) is a mean value of Ga concentrations (%) from an EPMA analysis of the magnetostriction element at five arbitrarily chosen points on the x-y plane of the principal surface. The rest is the Fe concentration (at %).

In all of Examples 1 to 6 and Comparative Examples 1 and 2, Lmax occurred when the angle θ was in region R, and Lmin occurred when the angle θ was in region P, as shown in Table 1.

In Comparative Examples 1 and 2, the monocrystalline alloys were not subjected to a heat treatment after being cut. In Comparative Examples 1 and 2, there is no angle difference from the <100> crystal orientation in x-y plane. However, because of the different cut sites, there was variation with different Ga concentrations of 15.2 at % and 18.2 at %. Accordingly, Comparative Examples 1 and 2 had greatly different Lmax (ppm) values, and greatly different Lmin (ppm) values. That is, the result indicates that large variation can occur in the magnetostriction characteristics, specifically, the magnetostriction characteristics concerning Lmax and Lmin measured along the longitudinal direction (y-axis direction), even in magnetostriction elements cut out from the same monocrystalline alloy in a direction that aligns with the <100> crystal orientation in the x-y plane.

In Examples 1 to 6, the monocrystalline alloys were subjected to a heat treatment after being cut. By comparing Examples 1 to 3 and Examples 4 to 6, because of the different cut sites, the Ga concentration was about 15.0 at % to 15.2 at % in Examples 1 to 3, and about 18.1 at % to 18.3 at % in Examples 4 to 6. That is, there was variation in Ga concentration, as large as that observed in Comparative Examples 1 and 2. However, Examples 1 to 6 had similar Lmax (ppm) and Lmin (ppm) values, indicating that magnetostriction elements cut out from the same monocrystalline alloy with the <100> crystal orientation aligning only along the longitudinal direction (y-axis direction) can have small variation in magnetostriction characteristics. Specifically, the result indicates that the magnetostriction elements have similar magnetostriction characteristics concerning Lmax and Lmin measured along the longitudinal direction (y-axis direction).

In Examples 1 to 3 and in Examples 4 to 6, the angle difference from the <100> crystal orientation of the x-y plane is different, specifically, 00, 22.50, and 450. However, Examples 1 to 6 had similar Lmax (ppm) values and similar Lmin (ppm) values, showing that the magnetostriction elements had small variation in magnetostriction characteristics, as demonstrated above. This result indicates that magnetostriction elements can have small variation in magnetostriction characteristics, specifically, magnetostriction characteristics concerning Lmax and Lmin, even when there is large variation in the direction in which the monocrystalline alloy is cut, provided that the cut direction is parallel to the <100> crystal orientation of the monocrystalline alloy only for the longitudinal direction of the x-y plane. This provides a margin in producing the magnetostriction element, meaning that the yield could improve.

When the magnetostriction element is to be used in applications such as in a magnetostriction-type vibration-powered generator, it is desirable for increased power output that the magnetostriction level shows a large positive value when the angle θ is in a region near the longitudinal direction of the magnetostriction element, namely, in region R (80°≤θ≤90°). Compared to the magnetostriction elements of Comparative Examples 1 and 2, the magnetostriction elements of Examples 1 to 6 show sufficiently higher and more similar magnetostriction levels when the angle θ is in region R, regardless of the Ga concentration (at %) due to the cut site of the monocrystalline alloy. This makes the magnetostriction element suitable for use in devices such as magnetostriction-type vibration-powered generators.

The foregoing results for the magnetostriction elements of Examples 1 to 6 are based on the binary monocrystalline alloy Fe_{(100-α)}Ga_{α}. However, the same effect should be obtained for the ternary monocrystalline alloy Fe_{(100-α-β)}Ga_{α}X_{β} (α and β represent the Ga content (at %) and the X content (at %), respectively, X is at least one element selected from the group consisting of Sm, Eu, Gd, Tb, Dy, Cu, and C, and the formula satisfies 14≤α≤19, and 0.5≤β≤1). This is likely because the elements other than Fe are 20 at % or less in terms of an amount of solid solution against Fe, and the amount is sufficiently smaller than the probable solid solubility limit of 30 at % against Fe, making it possible to retain the crystal structure, and produce the same effect obtained with the binary monocrystalline alloy Fe_{(100-α)}Ga_{α}. When contained in the monocrystalline alloy, the third element does not appear to change its concentration with the growth time of the monocrystalline alloy. This is because of the much lower melting point of gallium, causing this element to vaporize before the other elements. Another reason is that the third element is added only in trace amounts.

A magnetostriction element manufacturing method of the present disclosure enables manufacture of an FeGa-base magnetostriction element that has specific characteristics with regards to magnetostriction along the longitudinal direction, and that shows a sufficiently high magnetostriction level along the longitudinal direction. The magnetostriction elements obtained by cutting the FeGa-base monocrystalline alloy using the method can thus have small variation in magnetostriction characteristics, and can be manufactured with improved yield. This makes the magnetostriction element actively applicable to, for example, social infrastructure, and magnetostriction-type vibration-powered generators for stand-alone power systems used for monitoring of plant facilities.

What is claimed is:

1. A magnetostriction element comprised of a magnetostrictive material that is a monocrystalline alloy represented by following formula (1) or (2),
Fe_{(100-α)}Ga_{α} (1)
wherein α represents Ga content (at %), and satisfies 14≤α≤19,
Fe_{(100-α-β)}Ga_{α}X_{β} (2)
wherein α and β represent the Ga content (at %) and X content (at %), respectively, X is at least one element selected from a group consisting of Sm, Eu, Gd, Tb, Dy, Cu, and C, and the formula (2) satisfies 14≤α≤19, and 0.5≤β≤1,
the magnetostriction element having a longitudinal direction with a first dimension, and a transverse direction with a second dimension smaller than the first dimension, the transverse direction being orthogonal to the longitudinal direction, and the longitudinal direction being parallel to a <100> crystal orientation of the monocrystalline alloy,
the magnetostriction element, under a magnetic field applied parallel to an x-y plane formed by an x-axis representing the transverse direction and a y-axis representing the longitudinal direction and within an angle θ of 0°≤θ≤90° from an origin of the x-y plane with respect to the x-axis, having an Lmax with the angle θ of applied magnetic field satisfying 80°≤θ≤90°, and an Lmin with the angle θ of applied magnetic field satisfying 0°≤θ≤10°, wherein Lmax is a maximum value of magnetostriction level L measured along the y-axis direction, and Lmin is a minimum value of magnetostriction level L measured along the y-axis direction, and
the Lmax and the Lmin satisfying 0≤Lmin≤Lmax/10, and 100 ppm≤Lmax≤1,000 ppm.

2. The magnetostriction element according to claim 1, wherein the magnetostriction element has a form of a plate with two opposing principal surfaces, and the two opposing principal surfaces are parallel to the x-y plane.

3. A method for manufacturing a magnetostriction element, the method comprising:
producing a monocrystalline alloy represented by following formula (1) or (2),
Fe_{(100-α)}Ga_{α} (1)
wherein α represents Ga content (at %), and satisfies 14≤α≤19,
Fe_{(100-α-β)}Ga_{α}X_{β} (2)
wherein α and β represent the Ga content (at %) and X content (at %), respectively, X is at least one element selected from the group consisting of Sm, Eu, Gd, Tb, Dy, Cu, and C, and the formula (2) satisfies 14≤α≤19, and 0.5≤β≤1;
cutting the monocrystalline alloy into a shape having a longitudinal direction with a first dimension, and a transverse direction with a second dimension smaller than the first dimension, the transverse direction being orthogonal to the longitudinal direction, and the longitudinal direction being parallel to the <100> crystal orientation of the monocrystalline alloy; and
subjecting the cut monocrystalline alloy to a heat treatment at 400° C. or more to 700° C. or less,
the monocrystalline alloy being cut before or after the heat treatment.

4. The method according to claim 3, wherein cutting of the monocrystalline alloy further includes cutting the monocrystalline alloy to have a form of a plate with two opposing principal surfaces.

5. The method according to claim 3, wherein subjecting the cut monocrystalline alloy to the heat treatment further includes performing the heat treatment in an inert gas atmosphere.

6. The method according to claim 3, wherein the producing, cutting and subjecting the monocrystalline alloy to the heat treatment produce the magnetostriction element having an Lmax when an angle θ of an applied magnetic field satisfies 80°≤θ≤90°, and an Lmin when the angle θ of the applied magnetic field satisfies 0°≤θ≤10°, wherein Lmax is a maximum value of magnetostriction level L measured along a y-axis direction representing the longitudinal direction, and Lmin is a minimum value of magnetostriction level L measured along the y-axis direction.

7. A magnetostriction element comprised of a magnetostrictive material that is a monocrystalline alloy represented by formula (1),
Fe_{(100-α)}Ga_{α} (1)
wherein α represents the Ga content (at %), and satisfies 14≤α≤19,
the magnetostriction element having a longitudinal direction with a first dimension, and a transverse direction with a second dimension smaller than the first dimension, the transverse direction being orthogonal to the longitudinal direction, and the longitudinal direction being parallel to a <100> crystal orientation of the monocrystalline alloy,
the magnetostriction element, under a magnetic field applied parallel to an x-y plane formed by an x-axis representing the transverse direction and a y-axis representing the longitudinal direction and within an angle θ of 0°≤θ≤90° from an origin of the x-y plane with respect to the x-axis, having an Lmax with the angle θ of applied magnetic field satisfying 80°≤θ≤90°, and an Lmin with the angle θ of applied magnetic field satisfying 0°≤θ≤10°, wherein Lmax is a maximum value of magnetostriction level L measured along the y-axis direction, and Lmin is a minimum value of magnetostriction level L measured along the y-axis direction, and
the Lmax and the Lmin satisfying 0≤Lmin≤Lmax/10, and 100 ppm≤Lmax≤1,000 ppm.
